(19) United States
(12) Patent Application Publication
(10) Pub. No.: US 2026/0013312 A1
(43) Pub. Date: Jan. 8, 2026

(54) PHOTOSENSITIVE ORGANIC INSULATING MATERIAL COMPOSITION, INSULATING FILM, GATE INSULATING FILM, TRANSISTOR, ELECTRONIC DEVICE, AND METHOD FOR MANUFACTURING TRANSISTOR

(71) Applicant: NIKON CORPORATION, Tokyo (JP)

(72) Inventors: Kentaro YAMADA, Fujisawa-shi (JP); Yusuke KAWAKAMI, Yokohama-shi (JP); Shohei KOIZUMI, Atsugi-shi (JP)

(73) Assignee: NIKON CORPORATION, Tokyo (JP)

(21) Appl. No.: 19/326,375

(22) Filed: Sep. 11, 2025

Related U.S. Application Data
(63) Continuation of application No. PCT/JP2023/010261, filed on Mar. 16, 2023.

(51) Int. Cl. H10K 10/46; G03F 7/004; G03F 7/033; H10K 71/00

(52) U.S. Cl. CPC H10K 10/471; G03F 7/0045; G03F 7/033; H10K 71/00

(57) ABSTRACT

An objective of the present invention is to provide a photosensitive organic insulating composition having sufficient absorption, even of i-line radiation, as a photosensitive organic insulating composition that has little influence on device reliability and that is capable of forming a gate insulating film for transistors. An objective of the present invention is also to provide a gate insulating film and a transistor. A photosensitive organic insulating composition according to one embodiment of the present invention contains a chalcone compound and polyvinyl cinnamate.

### TECHNICAL FIELD

The present invention relates to a photosensitive organic insulating material composition, an insulating film, a gate insulating film, a transistor, an electronic device, and a method for manufacturing a transistor.

### BACKGROUND ART

As an organic insulating film material used in organic electronics such as organic thin-film transistors (OTFTs), materials having photosensitivity that allow direct patterning are sometimes employed. For example, Non-Patent Literature 1 discloses an OTFT using polyvinyl cinnamate (also referred to as poly(vinyl cinnamate), hereinafter sometimes referred to as PVCi) as a gate insulating film. However, when light used for exposure is i-line (wavelength: 365 nm), PVCi exhibits very low absorption of i-line, requiring an extremely large exposure dose for curing when using an i-line monochromatic light source. Against this background, there has been a demand for a photosensitive organic insulating composition that maintains insulating properties comparable to PVCi while having high i-line absorption and requiring a lower exposure dose even with an i-line monochromatic light source.

### PRIOR ART LITERATURE

### Non-Patent Literature

Non-Patent Literature 1: Feng, L. et al. Unencapsulated Air-stable Organic Field Effect Transistor by All Solution Processes for Low Power Vapor Sensing. Sci. Rep. 6, 20671; doi: 10.1038/srep20671 (2016).

### SUMMARY OF THE INVENTION

A first aspect of the present invention is a photosensitive organic insulating material composition comprising a chalcone compound and polyvinyl cinnamate.

A second aspect of the present invention is an insulating film that is a photocured product of the photosensitive organic insulating material composition of the first aspect.

A third aspect of the present invention is a gate insulating film that is a photocured product of the photosensitive organic insulating material composition of the first aspect.

A fourth aspect of the present invention is a transistor having the gate insulating film of the third aspect.

A fifth aspect of the present invention is an electronic device having the thin-film transistor of the fourth aspect.

A sixth aspect of the present invention is a method for manufacturing a gate insulating film, comprising a step of applying the photosensitive organic insulating material composition of the first aspect onto a substrate and a step of curing the photosensitive organic insulating material composition by exposure to form a gate insulating film.

A seventh aspect of the present invention is a method for manufacturing a transistor, comprising a step of forming a gate insulating film by the method for manufacturing a gate insulating film of the sixth aspect.

### BRIEF DESCRIPTION OF THE DRAWINGS

FIG. 1 Diagrams showing cross-sectional structures of organic thin-film transistors: (a) bottom-gate top-contact organic thin-film transistor; (b) bottom-gate bottom-contact organic thin-film transistor; (c) top-gate top-contact organic thin-film transistor; (d) top-gate bottom-contact organic thin-film transistor.

FIG. 2 A schematic cross-sectional view showing the structure of a bottom-gate bottom-contact organic thin-film transistor of Example 1.

FIG. 3 A schematic diagram of a Metal-Insulator-Metal structure fabricated to evaluate the electrical properties of the organic insulating film obtained from the composition prepared in Example 1.

FIG. 4 A graph showing the residual film ratio versus exposure dose for the insulating films obtained in Examples 1, 6, and Comparative Example 1.

FIG. 5 An enlarged view of FIG. 4, showing the residual film ratio versus exposure dose for the insulating films obtained in Examples 1, 6, and Comparative Example 1.

FIG. 6 A graph showing the leakage current between the upper and lower electrodes of the MIM structure shown in FIG. 3 for Examples 1, 6, and Comparative Example 1.

FIG. 7 Diagrams illustrating the method for manufacturing an organic thin-film transistor in Examples 1, 16.

FIG. 8 A microscope image of the completed OTFT in Example 1.

FIG. 9 Graphs showing the transfer characteristics and bias stress test results of the fabricated OTFT.

FIG. 10 A graph showing the threshold voltage shift of the fabricated OTFT.

FIG. 11 A graph showing the residual film ratio versus exposure dose for the insulating film obtained in Example 16.

FIG. 12 An enlarged view of FIG. 11, showing the residual film ratio versus exposure dose for the insulating film obtained in Example 16.

FIG. 13 A graph showing the leakage current between the upper and lower electrodes of the MIM structure shown in FIG. 3 for Example 16 and Comparative Example 1.

FIG. 14 A microscope image of the completed OTFT in Example 16.

FIG. 15 Graphs showing the transfer characteristics and bias stress test results of the OTFT fabricated in Example 16.

FIG. 16 Graphs showing the transfer characteristics and bias stress test results of the OTFT fabricated in Comparative Example 1.

### DESCRIPTION OF EMBODIMENTS

### (Photosensitive Organic Insulating Material Composition)

Hereinafter, a photosensitive organic insulating material composition of the present invention will be described in detail with reference to a first embodiment and a second embodiment.

### First Embodiment

The photosensitive organic insulating material composition of the first embodiment comprises a chalcone compound and polyvinyl cinnamate (PVCi).

### <Chalcone Compound>

The chalcone compound includes chalcone (unsubstituted chalcone) and chalcone derivatives such as substituted chalcones. Examples of substituted chalcones include chalcones having at least one substituent selected from the group consisting of an alkyl group having 1 to 5 carbon atoms, an alkoxy group having 1 to 5 carbon atoms, a polyoxyalkyl group having 1 to 5 carbon atoms, an alkylamino group having 1 to 5 carbon atoms, a thioalkyl group having 1 to 5 carbon atoms, a sulfonyl group having 1 to 5 carbon atoms, a nitro group, and a cyano group. Among these, chalcones having at least one substituent selected from the group consisting of an alkyl group having 1 to 5 carbon atoms, an alkoxy group having 1 to 5 carbon atoms, and a polyoxyalkyl group having 1 to 5 carbon atoms are preferred. The number of substituents is preferably 1 to 3, more preferably 1. The substitution position is preferably on the benzene ring on the alkene side of the unsaturated carbonyl, and more preferably at the ortho or para position. From the viewpoints of facilitating photodimerization reaction and increasing i-line absorption, a chalcone substituted with one alkoxy group having 1 to 5 carbon atoms at the para position of the benzene ring on the alkene side of the unsaturated carbonyl is preferred, and an alkoxy group having 1 to 3 carbon atoms is more preferred.

Specific examples of chalcone compounds include chalcone and methoxychalcone. Chalcone, 2-methoxychalcone, and 4-methoxychalcone are more preferred, and 4-methoxychalcone (hereinafter sometimes simply referred to as methoxychalcone) is even more preferred.

The chalcone compound according to the present embodiment may be used singly or in combination of two or more.

### <Polyvinyl Cinnamate (PVCi)>

Polyvinyl cinnamate, also known as poly(vinyl cinnamate), can be obtained, for example, from Sigma-Aldrich Japan K.K.

### <Solvent>

The photosensitive organic insulating material composition of the present embodiment may further comprise a solvent. Examples of solvents include alcohol-based solvents, ester-based solvents, hydrocarbon-based aromatic solvents, amide-based solvents, ketone-based solvents, glycol ether-based solvents, and ether-based solvents. From the viewpoints of solubility and film-forming properties, ester-based solvents and ketone-based solvents are preferred, among these, propylene glycol 1-monomethyl ether 2-acetate (PGMEA) and cyclopentanone being particularly preferred.

### <Other Components>

To improve weather resistance and light resistance, known antioxidants, light stabilizers, or ultraviolet absorbers may be added. To improve adhesion, known adhesion promoters may be added. To improve leveling properties, surface wettability, or hydrophobicity, known surface modifiers may be added.

### <Composition Ratio>

The photosensitive organic insulating material composition of the present embodiment may comprise the chalcone compound and polyvinyl cinnamate in the following mass ratio. The ratio of the total mass of the chalcone compound to the mass of polyvinyl cinnamate is 0.01 to 1, preferably 0.01 to 0.3, more preferably 0.03 to 0.3, and even more preferably 0.05 to 0.1.

In the photosensitive organic insulating material composition of the present embodiment, the total amount of the chalcone compound and polyvinyl cinnamate is preferably 10% by mass to 30% by mass, more preferably 10% by mass to 15% by mass, with respect to 100% by mass of the total composition.

In the photosensitive organic insulating material composition of the present embodiment, the total amount of the chalcone compound is preferably 0.1% by mass to 15% by mass, more preferably 0.1% by mass to 3% by mass, with respect to 100% by mass of the total composition.

<i-Line Sensitivity of the Composition>

The photosensitive organic insulating material composition of the present embodiment preferably has an absorption spectrum peak in the wavelength range of 300 to 370 nm, more preferably in the wavelength range of 320 to 370 nm, even more preferably in the wavelength range of 340 to 370 nm, and most preferably at the i-line (365 nm). Since the photosensitive organic insulating material composition of the present embodiment contains a chalcone compound in addition to polyvinyl cinnamate, it exhibits greater i-line absorption compared to a composition containing only polyvinyl cinnamate. As a result, when using an i-line exposure machine with the same light intensity, the time required for photocuring is reduced. It is possible to significantly improve productivity.

The absorbance intensity at the i-line of the photosensitive organic insulating material composition of the present embodiment can be adjusted by types of the chalcone compound, content of the chalcone compound, or the like. For example, when the chalcone compound is unsubstituted chalcone, the content is preferably 10% by mass to 50% by mass with respect to 100% by mass of the solid content (components excluding the solvent) of the photosensitive organic insulating material composition. When the chalcone compound is methoxychalcone, the content is preferably 5% by mass to 25% by mass.

### Second Embodiment

The photosensitive organic insulating material composition of the second embodiment comprises a polymer having a chalcone skeleton.

### <Polymer Having a Chalcone Skeleton>

The chalcone skeleton in the polymer according to the present embodiment refers to a structure derived from the various chalcone compounds included in the photosensitive organic insulating material composition of the first embodiment. The chalcone compound according to the present embodiment has the same meaning as the chalcone compound according to the first embodiment, and its preferred examples are also the same. The chalcone skeleton in the polymer according to the present embodiment is preferably a structure which is included in a side chain linked to a main chain of the polymer.

The main chain of the polymer according to the present embodiment is preferably a vinyl polymer chain formed by a polymerization reaction of a monomer having an ethylenically unsaturated bond.

The polymer having a chalcone skeleton according to the present embodiment preferably has a vinyl polymer main chain and a side chain containing a chalcone skeleton.

In addition to the vinyl polymer main chain and the side chain containing a chalcone skeleton, the polymer having a chalcone skeleton according to the present embodiment may include a side chain not containing a chalcone skeleton. However, it is preferable that the polymer does not include other side chains apart from the vinyl polymer main chain and the side chain containing a chalcone skeleton.

The polymer having a chalcone skeleton according to the present embodiment is preferably a polymer or copolymer of a monomer containing a substituted chalcone compound having an ethylenically unsaturated group. The substituted chalcone compound having an ethylenically unsaturated group is preferably at least one selected from the group consisting of a chalcone having an ethylenically unsaturated group and a chalcone having both an ethylenically unsaturated group and a methoxy group.

Specific examples of the polymer having a chalcone skeleton according to the present embodiment include polymers represented by the following formulas (1) to (3).

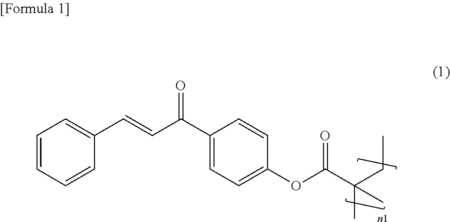

(wherein n1 is an integer from 1 to 1000.)

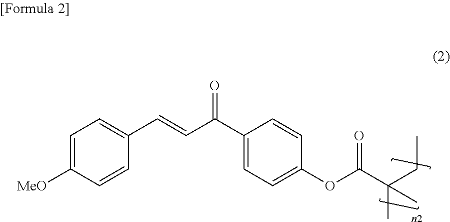

(wherein n2 is an integer from 1 to 1000.)

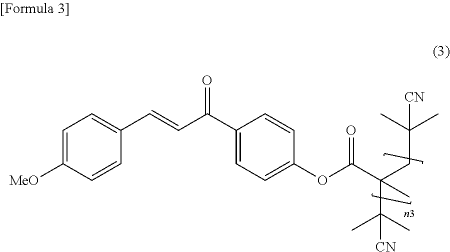

(wherein n3 is an integer from 1 to 1000.)

The weight average molecular weight of the polymer having a chalcone skeleton according to the present embodiment is preferably 5,000 to 100,000, more preferably 10,000 to 80,000, and even more preferably 20,000 to 50,000.

The weight average molecular weight can be measured by gel permeation chromatography (GPC).

In the polymer having a chalcone skeleton according to the present embodiment, the content of the chalcone skeleton (a structure derived from a chalcone compound, for example, the structure of compound 3 in the scheme below excluding the —OH group) is preferably 20% by mass to 97% by mass, more preferably 50% by mass to 80% by mass, with respect to 100% by mass of the polymer.

### <Method for Manufacturing a Polymer Having a Chalcone Skeleton>

The method for manufacturing a polymer having a chalcone skeleton according to the present embodiment will be described in detail below, using the polymer of formula (2) as an example.

The method for manufacturing the polymer according to the present embodiment comprises a step of synthesizing an ethylenically unsaturated compound having a chalcone skeleton and a polymerization step of polymerizing the ethylenically unsaturated compound to form a vinyl polymer main chain.

The ethylenically unsaturated compound having a chalcone skeleton can be produced by a known method of reacting a compound having a hydroxy group and a chalcone skeleton with an acid chloride having an ethylenically unsaturated group in a solvent. For example, as shown in Scheme 1 below, compound 3 is synthesized by the method described in Non-Patent Literature 2. Examples of synthesizing the compound include a method of reacting the obtained phenol derivative compound 3 (or 4′-hydroxy-4-methoxychalcone manufactured from Biosynth) with compound 4 to synthesize compound 5.

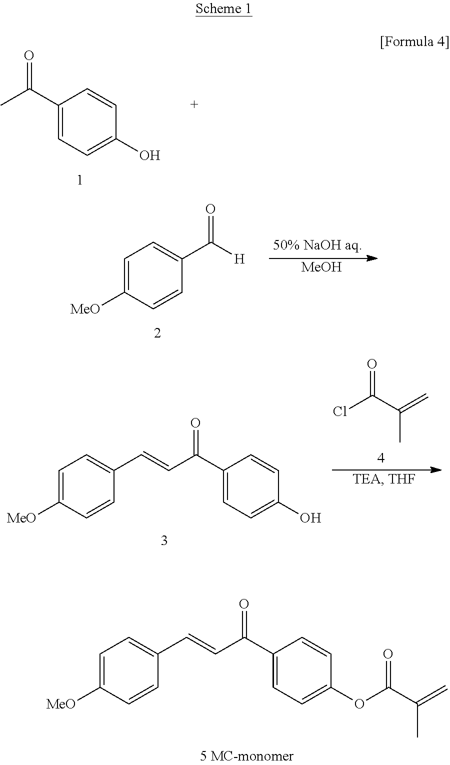

(Non-Patent Literature 2: X. Yang et al. Synthesis of a series of novel dihydroartemisinin derivatives containing a substituted chalcone with greater cytotoxic effects in leukemia cells, Bioorganic & Medicinal Chemistry Letters, Volume 19, Issue 15, (2009), Pages 4385-4388.)

In the polymerization step of polymerizing the ethylenically unsaturated compound, for example, when radically copolymerizing the ethylenically unsaturated compound, known methods such as solution polymerization, emulsion polymerization, suspension polymerization, and bulk polymerization can be used.

The solvent used in solution polymerization is not particularly limited as long as the monomer and the polymer of the present invention dissolve therein, and examples include toluene, xylene, diethyl ether, tetrahydrofuran, 1,4-dioxane, dimethylformamide, and dimethylsulfoxide. These solvents may also be used in combination.

The polymerization temperature is selected depending on the initiator used and is not particularly limited. The initiator is not particularly limited, and examples include azo-based initiators such as azoisobutyronitrile and peroxide-based initiators such as benzoyl peroxide and di(t-butyl) peroxide. A specific example is 2,2′-azobis(isobutyronitrile) (AIBN). The reaction time is not particularly limited and is set according to the half-life of the initiator used, but from an economic perspective, 4 to 30 hours is preferred.

For example, as shown in Scheme 2 below, compound 5 obtained above is polymerized to synthesize compound 6.

The conditions of the synthesis reaction will be described in detail in the Examples. The evaluation results of compound 6 will also be described in the Examples.

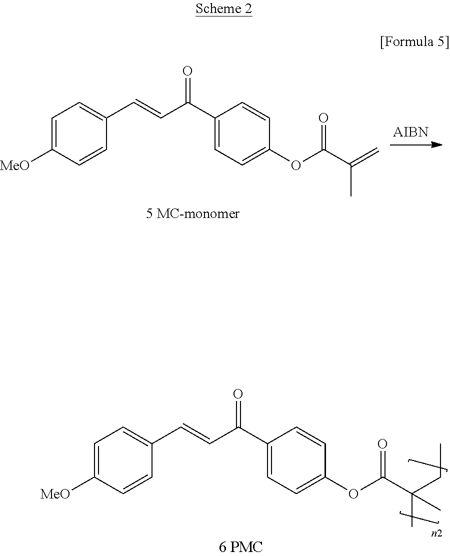

In the polymerization step, the ethylenically unsaturated monomer used as a raw material for the polymerization reaction may include an ethylenically unsaturated compound not having a chalcone skeleton in addition to an ethylenically unsaturated compound having a chalcone skeleton, such as compound 5 in Scheme 2. When an ethylenically unsaturated compound not having a chalcone skeleton is included, the resulting polymer includes side chains not containing a chalcone skeleton in addition to side chains containing a chalcone skeleton. In this case, the total mass of the ethylenically unsaturated compound not having a chalcone skeleton is preferably 0 to 50 parts by mass, more preferably 0 to 30 parts by mass, and even more preferably 0 parts by mass, with respect to 100 parts by mass of the total mass of the ethylenically unsaturated compound having a chalcone skeleton.

### <Solvent>

The photosensitive organic insulating material composition of the present embodiment may further comprise a solvent. Examples of solvents include alcohol-based solvents, ester-based solvents, and ketone-based solvents, and among these, propylene glycol 1-monomethyl ether 2-acetate (PGMEA) and cyclopentanone being preferred. The solvent used in the polymerization reaction may also be used as part of the solvent of the composition.

### <Other Components>

To improve weather resistance and light resistance, known antioxidants, light stabilizers, or ultraviolet absorbers may be added. To improve adhesion, known adhesion promoters may be added. To improve leveling properties, surface wettability, or hydrophobicity, known surface modifiers may be added.

### <Composition Ratio>

In the photosensitive organic insulating material composition of the present embodiment, the polymer having a chalcone skeleton is preferably 50% by mass to 100% by mass, more preferably 75% by mass to 100% by mass, and even more preferably 100% by mass, with respect to 100% by mass of the solid content (components excluding the solvent). The composition may include a chalcone compound and polyvinyl cinnamate in the mass ratio described above.

In the photosensitive organic insulating material composition of the present embodiment, the total amount of the polymer having a chalcone skeleton is preferably 10% by mass to 30% by mass, more preferably 10% by mass to 15% by mass, with respect to 100% by mass of the total composition.

<i-Line Sensitivity of the Composition>

The photosensitive organic insulating material composition of the present embodiment preferably has an absorption spectrum peak in the wavelength range of 300 to 370 nm, more preferably in the wavelength range of 320 to 370 nm, even more preferably in the wavelength range of 340 to 370 nm, and most preferably at the i-line (365 nm). Since the photosensitive organic insulating material composition of the present embodiment contains a polymer having a chalcone skeleton, it exhibits greater i-line absorption compared to a composition containing only polyvinyl cinnamate. As a result, when using an i-line exposure machine with the same light intensity, the time required for photocuring is reduced. It is possible to significantly improve productivity.

The absorbance intensity at the i-line of the photosensitive organic insulating material composition of the present embodiment can be adjusted by the type of chalcone compound with respect to the chalcone skeleton and the content of the chalcone skeleton in the polymer. For example, when the chalcone compound is methoxychalcone, i.e., a polymer having a methoxychalcone skeleton, the content is preferably 50 to 90 parts by mass. When i-line absorption is high, deep curing properties may decrease, leading to reduced photocuring performance in thick films or poor edge patterning. The content can be optionally adjusted to achieve excellent photocuring properties at the desired film thickness.

### (Organic Insulating Film)

The organic insulating film of one embodiment of the present invention (hereinafter referred to as the organic insulating film of the present embodiment) is obtained (as a photocured product) by forming a film of at least one selected from the group consisting of the photosensitive organic insulating material compositions of the first embodiment and the second embodiment (hereinafter sometimes referred to as the composition of the present embodiment) on a substrate and photocuring it. The composition of the present embodiment can be printed on various substrates. The organic solvent used is not particularly limited as long as it dissolves the compounds contained in the composition and does not dissolve materials such as organic semiconductors used in the manufacture of devices such as organic thin-film transistors. Examples include aromatic hydrocarbon solvents such as cyclohexane, benzene, toluene, xylene, ethylbenzene, isopropylbenzene, n-hexylbenzene, tetralin, decalin, isopropylbenzene, and chlorobenzene; chlorinated aliphatic hydrocarbon compounds such as methylene chloride and 1,1,2-trichloroethylene; aliphatic cyclic ether compounds such as tetrahydrofuran, tetrahydropyran, and dioxane; ketone compounds such as methyl ethyl ketone, cyclopentanone, and cyclohexanone; ester compounds such as ethyl acetate, dimethyl phthalate, methyl salicylate, amyl acetate, and propylene glycol 1-monomethyl ether 2-acetate (PGMEA); alcohols such as n-butanol, ethanol, and iso-butanol; and 1-nitropropane, carbon disulfide, and limonene. These solvents may be mixed as needed. The organic solvents are preferably the same as the organic solvents used for synthesis, and among these, propylene glycol 1-monomethyl ether 2-acetate (PGMEA) and cyclopentanone being more preferred.

There are no particular limitations on the coating or printing method, and examples of these methods include spin coating, drop casting, dip coating, doctor blade coating, pad printing, squeegee coating, roll coating, rod bar coating, air knife coating, wire bar coating, flow coating, gravure printing, flexographic printing, screen printing, inkjet printing, and relief reverse printing.

The composition of the present embodiment has a photocrosslinkable group with photodimerization reactivity, and radiation is preferably used for the photocrosslinking. Examples of radiation include ultraviolet and visible light with a wavelength of 245 to 450 nm. From the viewpoint of maximizing the effects of the present invention, the i-line region is preferred, and an i-line monochromatic light source is more preferred. The radiation dose is appropriately adjusted depending on the composition of the polymer, but examples include 100 to 300 mJ/cm², preferably 50 to 200 mJ/cm² to prevent a decrease in crosslinking degree and to improve economic efficiency by shortening the process time. The environment for irradiating ultraviolet or visible light is not particularly limited and can be performed in air, an inert gas, or under a certain amount of inert gas flow. If necessary, a photosensitizer may be added to the composition to promote the photocrosslinking reaction. There are no particular limitations on the photosensitizer used, and examples include benzophenone compounds, anthraquinone compounds, thioxanthone compounds, and nitrophenyl compounds. These sensitizers may be used in combination of two or more as needed. From the viewpoint of enhancing the electrical properties of the organic insulating film of the present embodiment, it is preferable that the composition substantially does not contain a photosensitizer. Here, a photosensitizer refers to a substance that plays a role in assisting the photocrosslinking reaction process by transferring the acquired energy, by absorbing light, to another substance. Examples of the photosensitizers include benzophenone compounds, anthraquinone compounds, thioxanthone compounds, and nitrophenyl compounds. The chalcone compounds included in the photosensitive organic insulating material composition of the first embodiment, which absorb light and participate in the photocrosslinking reaction themselves, are not photosensitizers.

The term “substantially does not contain” means that the content is so low that no photosensitizing effect is observed, for example, the content is preferably in the range of 0% by mass to 0.05% by mass, more preferably 0% by mass to 0.01% by mass, even more preferably 0% by mass to 0.005% by mass, and most preferably 0% by mass, with respect to the composition of the present embodiment.

The photosensitive organic insulating material composition used in the organic insulating film of the present embodiment can be efficiently photocrosslinked in a short time. To achieve more efficient photocrosslinking in a shorter time, for example, when using the i-line, the light irradiation time is preferably within 2 minutes. Furthermore, from the viewpoint of suitable control of crosslinking time, for example, when using the i-line, the light irradiation time is more preferably within 1 minute.

The organic insulating film of the present embodiment can be suitably used as an insulating film for various devices such as organic thin-film transistors. The organic insulating film of the present embodiment is particularly suitable for use as a gate insulating film of organic thin-film transistors, as described below.

### (Organic Thin-Film Transistor)

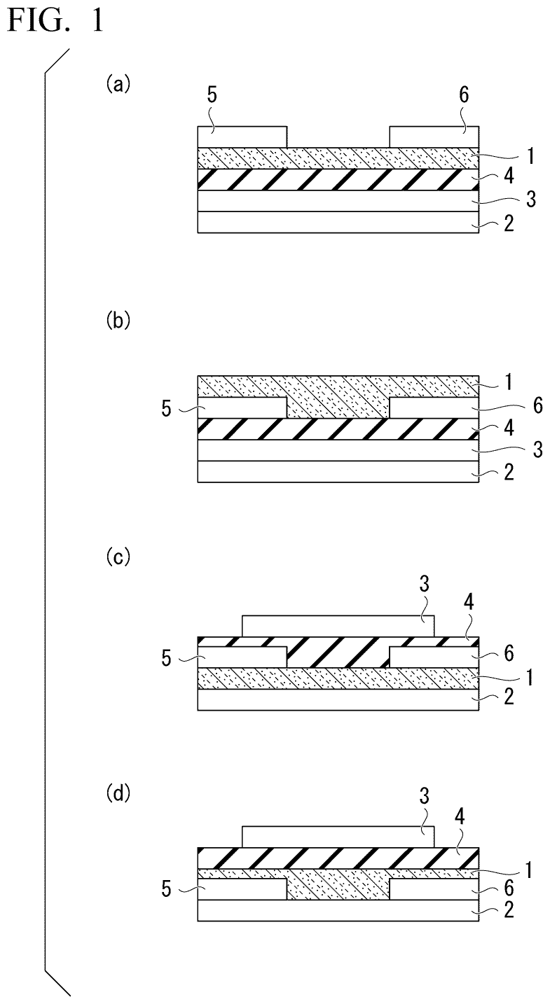

The organic thin-film transistor of the present embodiment may have any one of the element structures shown in FIG. 1: bottom-gate top-contact type (A), bottom-gate bottom-contact type (B), top-gate top-contact type (C), or top-gate bottom-contact type (D). The polymer of the present embodiment is particularly highly applicable to the element structures of types (A) and (B). In the Examples, an element of type (B) was used. Here, reference numeral 1 denotes an organic semiconductor layer, reference numeral 2 denotes a substrate, reference numeral 3 denotes a gate electrode, reference numeral 4 denotes a gate insulating layer, reference numeral 5 denotes a source electrode, and 6 denotes a drain electrode.

In the organic thin-film transistor, the substrate used is not particularly limited as long as it ensures sufficient flatness for fabricating the element, and examples include inorganic material substrates such as glass, quartz, aluminum oxide, highly-doped silicon, silicon oxide, tantalum dioxide, tantalum pentoxide, and indium tin oxide; plastics; metals such as gold, copper, chromium, titanium, and aluminum; ceramics; coated paper; and surface-coated nonwoven fabrics. Composite materials made of these materials or multilayered materials of these materials may also be used. The surfaces of these materials may be coated to adjust surface tension.

Examples of plastics used as the substrate include polyethylene terephthalate, polyethylene naphthalate, triacetyl cellulose, polycarbonate, polymethyl acrylate, polymethyl methacrylate, polyvinyl chloride, polyethylene, ethylene-vinyl acetate copolymer, poly(4-methyl-1-pentene), polypropylene, cyclic polyolefin, fluorinated cyclic polyolefin, polystyrene, polyimide, polyvinyl phenol, polyvinyl alcohol, poly(diisopropyl fumarate), poly(diethyl fumarate), poly(diisopropyl maleate), polyether sulfone, polyphenylene sulfide, polyphenylene ether, polyester elastomer, polyurethane elastomer, polyolefin elastomer, polyamide elastomer, and styrene block copolymer. Substrates made by laminating two or more of the above plastics may also be used.

Examples of conductive materials for the gate electrode, source electrode, or drain electrode include gold, silver, aluminum, copper, titanium, platinum, chromium, polysilicon, silicide, indium tin oxide (ITO), and tin oxide. Multiple conductive materials may be laminated for use.

In bottom-gate top-contact type (A) and bottom-gate bottom-contact type (B) elements, electrodes are formed on the organic semiconductor layer or the gate insulating film. The method for forming electrodes is not particularly limited, and examples include evaporation, high-frequency sputtering, and electron beam sputtering. Alternatively, methods such as solution spin coating, drop casting, dip coating, doctor blade coating, die coating, pad printing, roll coating, gravure printing, flexographic printing, screen printing, inkjet printing, and relief reverse printing using an ink in which nanoparticles of the conductive material are dissolved in water or an organic solvent can be employed. If necessary, a treatment to adsorb fluoroalkyl thiol, fluoroaryl thiol, or the like onto the electrode may be performed.

There are no particular limitations on the organic semiconductor used in the organic thin-film transistor of the present embodiment, and both N-type and P-type organic semiconductors can be used, as well as bipolar transistors combining N-type and P-type. Examples include polypyrroles, polythiophenes, polyanilines, polyallylamines, fluorenes, polycarbazoles, polyindoles, and poly(p-phenylene vinylenes). Low-molecular-weight materials soluble in organic solvents, such as polycyclic aromatic derivatives like pentacene, phthalocyanine derivatives, perylene derivatives, tetrathiafulvalene derivatives, tetracyanoquinodimethane derivatives, fullerenes, and carbon nanotubes, can also be used. Specific examples include a condensate of 9,9-di-n-octylfluorene-2,7-di(ethylene boronate) and 5,5′-dibromo-2,2′-bithiophene.

In the present embodiment, the method for forming the organic semiconductor layer is preferably a method of dissolving the organic semiconductor in an organic solvent and applying or printing it, but there are no limitations lo as ng as a thin film of the organic semiconductor layer can be formed. The solution concentration when printing a solution of the organic semiconductor dissolved in an organic solvent varies depending on the structure of the organic semiconductor and the solvent used, but from the viewpoints of forming a more uniform semiconductor layer and reducing the layer thickness, 0.5 to 5% by weight is preferred. There are no particular limitations on the organic solvent as long as the organic semiconductor dissolves at a certain concentration to enable film formation, and examples include hexane, heptane, octane, decane, dodecane, tetradecane, decalin, indane, 1-methylnaphthalene, 2-ethylnaphthalene, 1,4-dimethylnaphthalene, dimethylnaphthalene isomer mixtures, toluene, xylene, ethylbenzene, 1,2,4-trimethylbenzene, mesitylene, isopropylbenzene, pentylbenzene, hexylbenzene, tetralin, octylbenzene, cyclohexylbenzene, 1,2-dichlorobenzene, 1,3-dichlorobenzene, 1,4-dichlorobenzene, trichlorobenzene, 1,2-dimethoxybenzene, 1,3-dimethoxybenzene, γ-butyrolactone, 1,3-butylene glycol, ethylene glycol, benzyl alcohol, glycerin, cyclohexanol acetate, 3-methoxybutyl acetate, ethylene glycol monomethyl ether acetate, ethylene glycol monobutyl ether acetate, propylene glycol monomethyl ether acetate, anisole, cyclohexanone, mesitylene, 3-methoxybutyl acetate, cyclohexanol acetate, dipropylene glycol diacetate, dipropylene glycol methyl ether acetate, diethylene glycol monobutyl ether acetate, diethylene glycol monoethyl ether acetate, 1,6-hexanediol diacetate, 1,3-butylene glycol diacetate, 1,4-butanediol diacetate, ethyl acetate, phenyl acetate, dipropylene glycol dimethyl ether, dipropylene glycol methyl-n-propyl ether, tetradecahydrophenanthrene, 1,2,3,4,5,6,7,8-octahydrophenanthrene, decahydro-2-naphthol, 1,2,3,4-tetrahydro-1-naphthol, α-terpineol, isophorone triacetate decahydro-2-naphthol, dipropylene glycol dimethyl ether, 2,6-dimethylanisole, 1,2-dimethylanisole, 2,3-dimethylanisole, 3,4-dimethylanisole, 1-benzothiophene, 3-methylbenzothiophene, 1,2-dichloroethane, 1,1,2,2-tetrachloroethane, chloroform, dichloromethane, tetrahydrofuran, 1,2-dimethoxyethane, dioxane, cyclohexanone, acetone, methyl ethyl ketone, diethyl ketone, diisopropyl ketone, acetophenone, N,N-dimethylformamide, N-methyl-2-pyrrolidone, and limonene. To obtain a crystalline film with preferred properties, solvents with high solubility for the organic semiconductor and a boiling point of 100° C. or higher are suitable, and examples of the solvents include xylene, isopropylbenzene, anisole, cyclohexanone, mesitylene, 1,2-dichlorobenzene, 3,4-dimethylanisole, pentylbenzene, tetralin, cyclohexylbenzene, and decahydro-2-naphthol. Mixed solvents combining two or more of the above solvents in appropriate ratios can also be used.

If necessary, various organic or inorganic polymers or oligomers, or organic or inorganic nanoparticles can be added to the organic semiconductor layer as a solid or as a dispersion of nanoparticles in water or an organic solvent. A protective film can be formed by applying a polymer solution onto the polymer dielectric layer. Further, if necessary, various moisture-resistant coatings, light-resistant coatings, etc., can be applied onto the protective film.

Examples of conductive materials for the gate electrode, source electrode, or drain electrode in the organic thin-film transistor of the present embodiment include conductive materials of inorganic electrodes such as aluminum, gold, silver, copper, doped silicon, polysilicon, silicide, tin oxide, indium oxide, indium tin oxide, chromium, platinum, titanium, tantalum, graphene, carbon nanotubes, and conductive materials of organic electrodes such as doped conductive polymers (e.g., PEDOT-PSS). Multiple conductive materials may be laminated for use. To improve carrier injection efficiency, surface treatment agents may be used to treat the surfaces of these electrodes. Examples of such surface treatment agents include benzenethiol and pentafluorobenzenethiol.

The method for forming electrodes on the substrate, insulating layer, or organic semiconductor layer is not particularly limited, and examples include evaporation, high-frequency sputtering, and electron beam sputtering. Alternatively, methods such as solution spin coating, drop casting, dip coating, doctor blade coating, die coating, pad printing, roll coating, gravure printing, flexographic printing, screen printing, inkjet printing, and relief reverse printing using an ink in which nanoparticles of the conductive material are dissolved in water or an organic solvent can be employed.

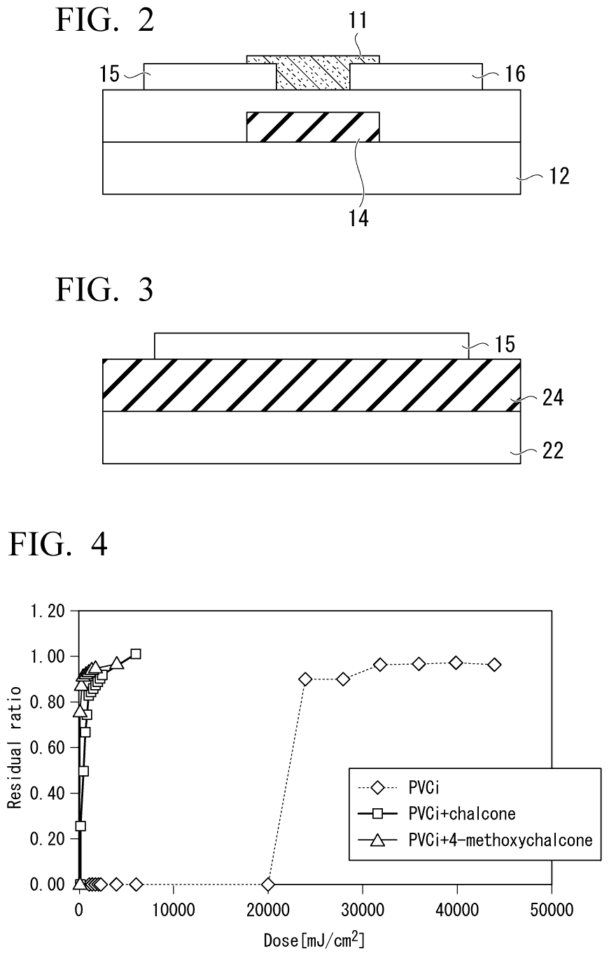

The organic thin-film transistor of the present embodiment can use, for example, an element of the bottom-gate bottom-contact type used in the Examples. FIG. 2 is a schematic cross-sectional view showing the structure of a bottom-gate bottom-contact organic thin-film transistor as an example of the present embodiment. This organic thin-film transistor comprises a substrate 2, a gate electrode 3 formed on the substrate 2, a gate insulating layer 4 formed on the gate electrode 3, a source electrode 5 and a drain electrode 6 formed on the gate insulating layer 4 with a channel portion therebetween, and an organic semiconductor layer 1 formed on the electrodes.

From the viewpoint of practical applicability of the organic thin-film transistor element, the organic thin-film transistor of the present embodiment preferably has a mobility of 0.20 cm²/Vs or higher.

From the viewpoint of practical applicability of the organic thin-film transistor element, the organic thin-film transistor of the present embodiment preferably has a threshold voltage of −10.0 V or higher and less than 0 V.

From the viewpoint of practical applicability of the organic thin-film transistor element, the organic thin-film transistor of the present embodiment preferably has a leakage current density of 10-9 A/cm² or lower.

### (Electronic Device Including Organic Thin-Film Transistor)

The electronic device of the present embodiment includes the organic thin-film transistor of the present embodiment. Examples of the electronic device of the present embodiment include organic electroluminescent elements, organic photovoltaic elements, and displays.

### EXAMPLES

Hereinafter, the present invention will be described by way of Examples, but the present invention is not limited to these Examples.

The raw materials and equipment used in the Examples of the present invention are described below.

### (Raw Materials)

Chalcone: Tokyo Chemical Industry Co., Ltd., Product Code C0071, Purity (Test Method): >98.0% (GC)
Methoxychalcone: Tokyo Chemical Industry Co., Ltd., Product Code M1409, Purity (Test Method): >98.0% (GC)
Polyvinyl cinnamate (PVCi): Sigma-Aldrich, Product Code 182648
Cyclopentanone: FUJIFILM Wako Pure Chemical Corporation, Product Code 039-09716, Purity (Test Method): >95.0% (GC)
PGMEA: Tokyo Chemical Industry Co., Ltd., Product Code P1171, Purity (Test Method): >98.0% (GC)
Silicon wafer: Shonan Electronic Materials Research Institute, P-type specific resistance 1 Ωcm or less
Glass substrate: Shonan Electronic Materials Research Institute, Soda lime
Organic semiconductor layer raw material: 2-Decyl-7-phenyl[1] benzothieno[3,2-b][1]benzothiophene, Tokyo Chemical Industry Co., Ltd., Product Code D5491, Purity (Test Method): >99.5% (HPLC)
Organic semiconductor layer additive raw material: Polystyrene, Sigma-Aldrich, Product Code 182427, average Mw about 280,000 (GPC)

### (Equipment)

Film-forming equipment: Spin coater (Manufactured by Mikasa Co., Ltd., MS-A150)
i-Line exposure machine: Multilight (Manufactured by Ushio Inc.) Photolithography
Weight average molecular weight: GPC (Manufactured by TOSOH Corporation, GPC-8020)
Residual film ratio: Stylus profiler (Manufactured by KLA-Tencor, P16)
Electrical property evaluation: Semiconductor parameter analyzer (Manufactured by Keithley Instruments, Inc., 4200A-SCS)

### (Evaluation Methods)

Average molecular weight: Calculated by GPC (Manufactured by TOSOH Corporation, GPC-8020)
Chalcone skeleton content: Calculated from the feed ratio of synthetic raw materials
Residual film ratio: Ratio of film thickness after exposure and development to film thickness before exposure
Leakage current: Obtained by current-voltage (I-V) measurement of the Metal-Insulator-Metal structure using a semiconductor parameter analyzer
Dielectric constant: Calculated from capacitance measurement of the Metal-Insulator-Metal structure using a semiconductor parameter analyzer
Transfer characteristics: Obtained by a semiconductor parameter analyzer
Threshold voltage shift by bias stress test: Obtained by Negative Bias Stress (NBS) test applying a constant voltage (VGS=−20 V) between the source and gate. The voltage was applied for 1, 10, 100, and 1000 seconds, and the threshold voltage shift was calculated by measuring the transfer characteristics after each duration of applying the voltage.

### Synthesis Example 1

### “Synthesis of a Compound Having a Hydroxy Group and a Methoxychalcone Skeleton (Compound 3 in Scheme 1)”

Compound 3: <Substance Name: 4′-Hydroxy-4-methoxychalcone>

Under an argon atmosphere, 4-hydroxyacetophenone (FUJIFILM Wako Pure Chemical Corporation, 390 g), p-anisaldehyde (FUJIFILM Wako Pure Chemical Corporation, 390 g), and methanol (FUJIFILM Wako Pure Chemical Corporation, 5.5 L) were mixed in a 20 L four-neck flask. Then, while maintaining the internal temperature at 15° C. or lower in an ice bath, a 50% NaOH aqueous solution (2.7 L) was added dropwise over 60 minutes. After removing the ice bath, the mixture was stirred at room temperature for 95 hours. Distilled water (5.4 L) was placed in a 90 L container, and the reaction solution was poured in. Then, a IN HCl aqueous solution (approximately 35 L) was added gradually. If the internal temperature was likely to exceed 30° C., ice was added to maintain it at about 25° C. The pH was adjusted to about 4, and the precipitated solid was separated by suction filtration and washed with a mixed solution of methanol and distilled water (2/1, 3 L). The obtained solid was dried under reduced pressure at 50° C. for 24 hours to obtain 544.6 g of a pale yellow solid. Recrystallization was performed using ethanol to obtain 520.8 g of the target compound as a pale yellow solid (yield: 71%).

The ¹H-NMR measurement results for 4′-hydroxy-4-methoxychalcone are shown below.

¹H-NMR (CDCl₃) 3.86 (3H, s), 5.52 (1H, s), 6.93 (4H, m), 7.41 (1H, m), 7.60 (2H, m), 7.81 (1H, m), 8.01 (2H, m)

### Synthesis Example 2

### “Synthesis of an Ethylenically Unsaturated Compound Having a Methoxychalcone Skeleton (Compound 5 in Scheme 1)”

Compound 5: <Substance Name: (E)-4-(3-(4-Methoxyphenyl)acryloyl)phenyl methacrylate>

Under an argon atmosphere, 4′-hydroxy-4-methoxychalcone (30.0 g) and THF (dry) were added to a 2 L four-neck flask and dissolved. Triethylamine (FUJIFILM Wako Pure Chemical Corporation, 15.5 g) was added, and after cooling with ice water, methacryloyl chloride (FUJIFILM Wako Pure Chemical Corporation, 14.8 g) was added dropwise, followed by stirring overnight. Water (600 mL) was poured into the reactor, and the mixture was transferred to a separatory funnel and extracted with ethyl acetate (FUJIFILM Wako Pure Chemical Corporation, 1.2 L). The ethyl acetate layer was washed twice with 5% sodium bicarbonate water (600 mL) and three times with water (600 mL), then dried with anhydrous sodium sulfate. After removing the drying agent, the mixture was concentrated under reduced pressure (40° C./20 mmHg) to obtain a pale yellow solid. Ethanol (600 mL) was added to the obtained crude product, stirred for 30 minutes, filtered to obtain a white solid, and dried under reduced pressure (40° C./<1 mmHg) to obtain 30.1 g (79.2%) of the target compound.

The ¹H-NMR measurement results for (E)-4-(3-(4-methoxyphenyl)acryloyl)phenyl methacrylate are shown below.

¹H-NMR (CDCl₃) 2.09 (3H, s), 3.87 (3H, s), 5.81 (1H, m), 6.39 (1H, m), 6.93 (2H, d), 7.26 (2H, d), 7.38 (1H, m), 7.63 (2H, d), 7.78 (1H, m), 8.08 (2H, d)

### Synthesis Example 3

### “Synthesis of a Polymer Having a Methoxychalcone Skeleton (PMC: Poly(4-Methoxychalcone)) (Compound Represented by Formula (2), Compound 6 in Scheme 2)”

As shown in Scheme 2 above, Compound 5 obtained in Synthesis Example 2 was polymerized to synthesize Compound 6.

Under an argon atmosphere, (E)-4-(3-(4-methoxyphenyl)acryloyl)phenyl methacrylate and degassed DMF were added to a 3 L four-neck flask and stirred. After AIBN (FUJIFILM Wako Pure Chemical Corporation, 3.82 g) was added, the temperature was raised to 60° C., and then the mixture was heated and stirred for 21 hours. After cooling, the mixture was added dropwise to methanol (30 L). After stirring for 60 minutes, the mixture was filtered under reduced pressure, washed three times with methanol (2 L), and the obtained solid was dried under reduced pressure (50° C./<1 mmHg) to obtain 135 g of the target PMC.

The ¹H-NMR measurement results for PMC are shown below.

¹H-NMR (CDCl₃) 1.57 (3H, br), 1.94 (1H, br), 3.75 (3H, br), 6.83 (2H, br), 7.31 (6H, m, br), 7.96 (2H, br)

The obtained compound 6 was evaluated for weight average molecular weight, chalcone skeleton content, and solid content, and the results are shown below. The evaluation methods are as described above.

Weight average molecular weight: 44,131

Chalcone skeleton content: 74 parts by mass

### Example 1

### [Preparation of Composition]

Chalcone (3% by mass) and polyvinyl cinnamate (10% by mass) were dissolved in cyclopentanone to prepare the composition of the present example.

### [Preparation and Evaluation of Organic Insulating Film]

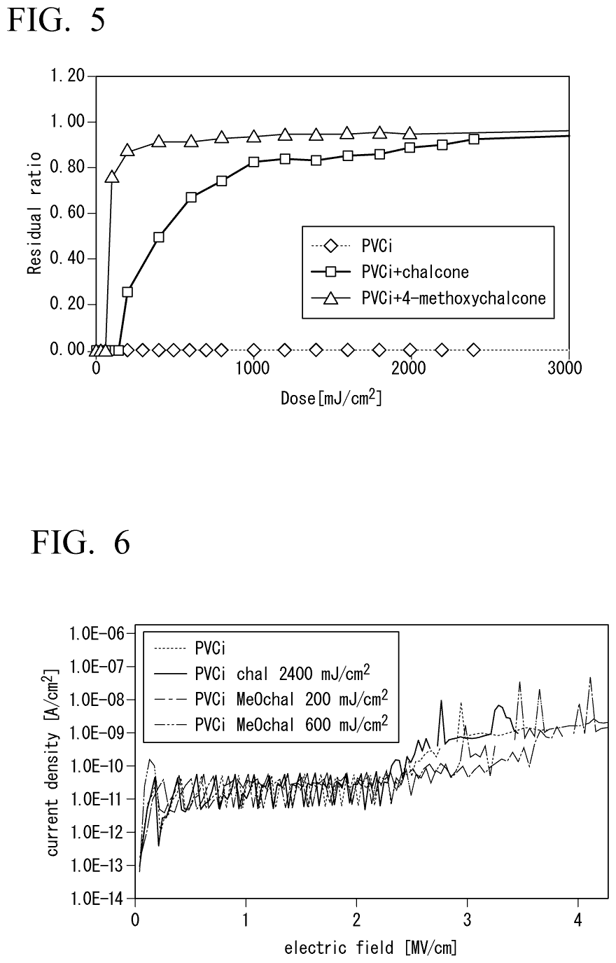

FIG. 3 is a schematic diagram of a Metal-Insulator-Metal structure fabricated to evaluate the electrical properties of the organic insulating film obtained from the composition prepared in the present example. The composition prepared in the present example was spin-coated onto a silicon wafer at 2000 rpm for 60 seconds to form a film. The film thickness before photolithography was 450 nm. Pre-baking was performed at 80° C. for 20 minutes, exposure was performed with various i-line exposure doses, and the organic insulating film was developed with PGMEA. FIG. 4 and FIG. 5 (an enlarged view of FIG. 4) show the residual film ratio versus exposure dose. As shown in FIG. 5, the residual film ratio reached approximately 1 at 2400 mJ/cm².

FIG. 6 shows the leakage current between the upper and lower electrodes of the MIM structure shown in FIG. 3.

From FIG. 6, it was found that the organic insulating film of Example 1 has insulating properties substantially equivalent to those of the organic insulating film of Comparative Example 1 described later.

The dielectric constant of the organic insulating film of Example 1 was also evaluated. The evaluation results of the organic insulating film of Example 1 are shown in Table 1.

### [Manufacture and Evaluation of Organic Thin-Film Transistor]

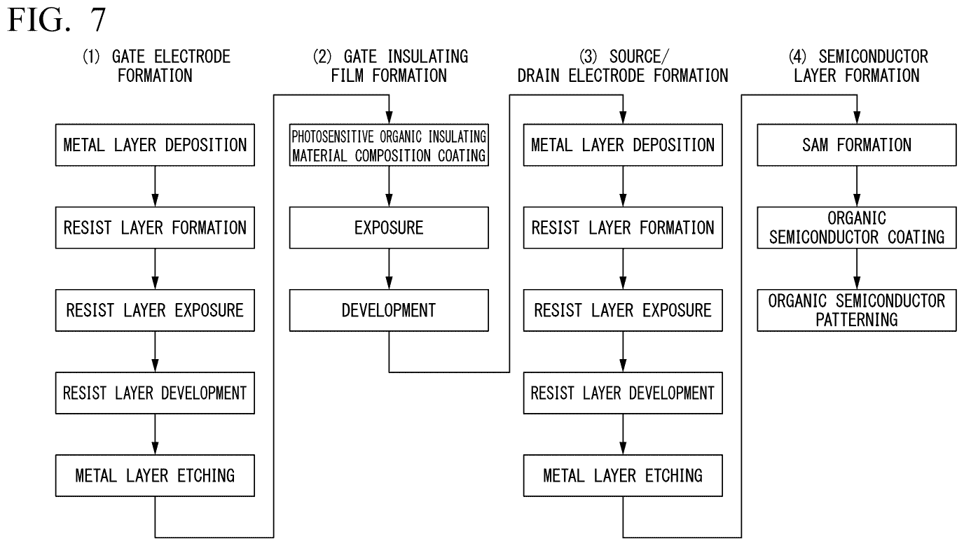

FIG. 7 illustrates the method for manufacturing an organic thin-film transistor according to the present embodiment. FIG. 2 is a schematic cross-sectional view showing the laminated structure of the manufactured organic thin-film transistor.

First, in the step of FIG. 7(1), a gate electrode was formed. Aluminum (Al) was deposited to a thickness of 50 nm on a soda lime wafer, which is an insulating substrate, by resistance heating vacuum evaporation. Electrode processing was then performed. A positive photoresist, Sumiresist PFI-34A (Sumitomo Chemical), was spin-coated onto the Al layer surface at 1500 rpm for 45 seconds, pre-baked at 105° C. for 10 minutes to remove the solvent from the resist film. The gate electrode pattern and was exposed with an i-line dose of 270 mJ/cm² using a photomask. Post-exposure baking (PEB) was performed at 105° C. for 10 minutes. The exposed resist was then removed by immersion in tetramethylammonium hydroxide (TMAH) at 25° C. for 1 minute. The substrate was washed with pure water, dried by blowing N₂ gas, and post-baked at 105° C. for 10 minutes. Next, the Al layer was processed by immersing the substrate in a heated mixed acid aqueous solution (H₃PO₄:CH₃COOH:HNO₃:H₂O=10:1:1:2 by weight) to etch the exposed Al. The resist on the substrate was removed with acetone, washed with pure water, and dried by blowing N₂ gas.

Next, in the step of FIG. 7(2), a gate insulating film was formed. The composition obtained in the present example was spin-coated at 2000 rpm for 60 seconds, pre-baked at 80° C. for 20 minutes, and cured with an i-line dose of 2400 mJ/cm² using a photomask. The substrate was then immersed in PGMEA as a developer at 25° C. to open only the pad portion of the gate electrode. Post-baking was performed at 150° C. for 1 hour.

Next, in the step of FIG. 7(3), source/drain electrodes were formed. Gold (Au) was deposited to a thickness of 50 nm on the gate insulating layer by resistance heating vacuum evaporation. Electrode processing was performed in the same manner as in the step of FIG. 7(1) for resist processing and etching processing.

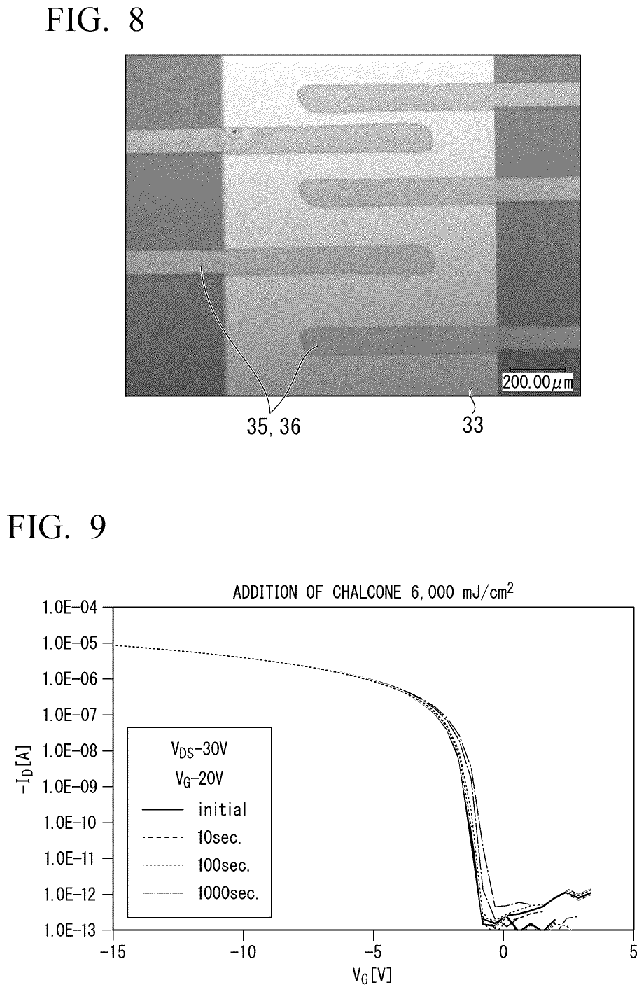

Finally, in the step of FIG. 7(4), the semiconductor layer was formed. After UV treatment of the substrate with the source/drain electrodes, a thiol-based self-assembled monolayer (SAM) was formed on the Au electrode surface by immersion. A semiconductor solution containing 0.5% by mass organic semiconductor and 0.2% by mass polystyrene dissolved in xylene was heated to 150° C., spin-coated at 1000 rpm for 30 seconds, and post-baked at 120° C. for 5 minutes. Finally, the semiconductor layer was patterned by wiping the electrode pads. The microscope image of the completed OTFT is shown in FIG. 8.

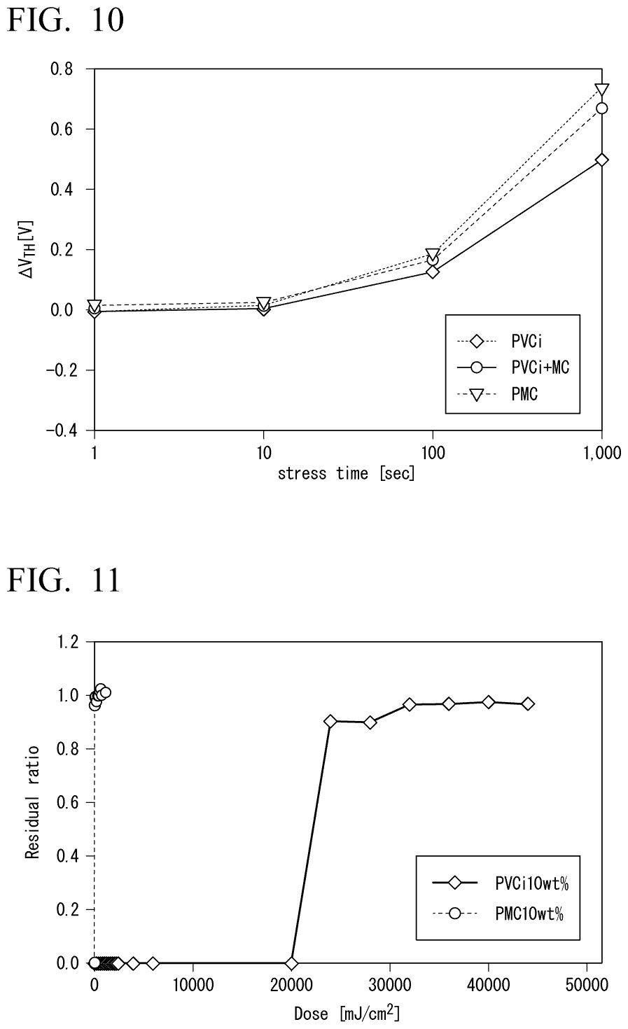

FIG. 9 shows the transfer characteristics and bias stress test results of the fabricated OTFT (channel length L=50 μm, channel width W=500 μm). The transfer characteristics were obtained at a source/drain voltage Vds=−2 V. The bias stress test was performed by applying a bias voltage Vg=−20 V between the source and gate, and the transfer characteristics were obtained after 1 second, 10 seconds, 100 seconds, and 1000 seconds of application. FIG. 10 shows the threshold voltage shift versus application time. For the gate insulating film of the present example, a threshold voltage shift of 0.5 V was confirmed after 1000 seconds of application.

### Examples 2 to 15

### [Preparation of Composition]

Compositions of Examples 2 to 15 were prepared with the compositions shown in Tables 1 and 2.

### [Preparation and Evaluation of Organic Insulating Film]

Organic insulating films were prepared and evaluated in the same manner as in Example 1, except that the compositions of Examples 2 to 15 were used instead of the composition of Example 1. The results are shown in Tables 1 and 2.

### [Manufacture and Evaluation of Organic Thin-Film Transistor]

Organic thin-film transistors were manufactured and evaluated in the same manner as in Example 1, except that the compositions of Examples 2 to 15 were used instead of the composition of Example 1. The results are shown in Tables 1 and 2.

### Example 16

### [Preparation of Composition]

The polymerized methoxychalcone film obtained in Synthesis Example 3 was dissolved in cyclopentanone at 10% by mass to prepare the composition of the present example.

### [Preparation and Evaluation of Organic Insulating Film]

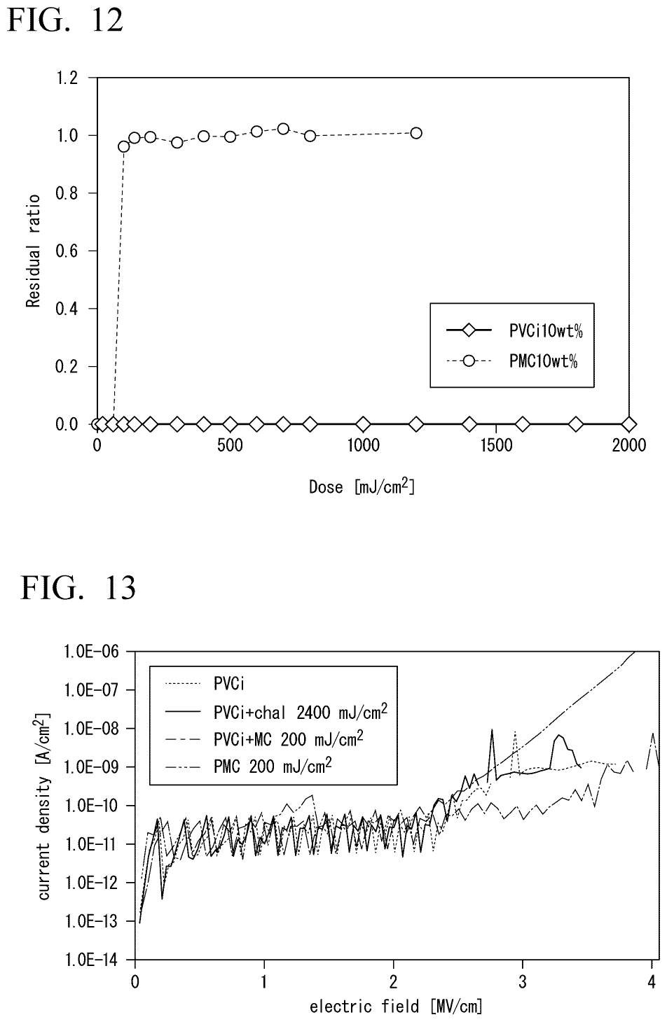

FIG. 3 is a schematic diagram of a Metal-Insulator-Metal structure fabricated to evaluate the electrical properties of the organic insulating film obtained from the composition prepared in the present example. The composition prepared in the present example was spin-coated onto a silicon wafer at 2000 rpm for 60 seconds to form a film. The film thickness before photolithography was 450 nm. Pre-baking was performed at 80° C. for 20 minutes, exposure was performed with various i-line exposure doses, and the organic insulating film was developed with cyclopentanone. FIG. 11 and FIG. 12 (an enlarged view of FIG. 11) show the residual film ratio versus exposure dose. As shown in FIG. 12, the residual film ratio reached approximately 1 at 200 mJ/cm².

FIG. 13 shows the leakage current between the upper and lower electrodes of the MIM structure shown in FIG. 3.

From FIG. 13, it was found that the organic insulating film of Example 16 has insulating properties substantially equivalent to those of the organic insulating film of Comparative Example 1 described later.

The dielectric constant of the organic insulating film of Example 16 was also evaluated.

The evaluation results of the organic insulating film of Example 16 are shown in Table 2.

### [Manufacture and Evaluation of Organic Thin-Film Transistor]

FIG. 7 illustrates the method for manufacturing an organic thin-film transistor according to the present embodiment. FIG. 2 is a schematic cross-sectional view showing the laminated structure of the manufactured organic thin-film transistor.

First, in the step of FIG. 7(1), a gate electrode was formed. Aluminum (Al) was deposited to a thickness of 50 nm on a soda lime wafer, which is an insulating substrate, by resistance heating vacuum evaporation. Electrode processing was then performed. A positive photoresist, Sumiresist PFI-34A (Sumitomo Chemical), was spin-coated onto the Al layer surface at 1500 rpm for 45 seconds, pre-baked at 105° C. for 10 minutes to remove the solvent from the resist film. The gate electrode pattern was and exposed with an i-line dose of 270 mJ/cm² using a photomask. Post-exposure baking (PEB) was performed at 105° C. for 10 minutes. The exposed resist was then removed by immersion in tetramethylammonium hydroxide (TMAH) at 25° C. for 1 minute. The substrate was washed with pure water, dried by blowing N₂ gas, and post-baked at 105° C. for 10 minutes. Next, the Al layer was processed by immersing the substrate in heated mixed a acid aqueous solution (H₃PO₄:CH₃COOH:HNO₃:H₂O=10:1:1:2 by weight) to etch the exposed Al. The resist on the substrate was removed with acetone, washed with pure water, and dried by blowing N₂ gas.

Next, in the step of FIG. 7(2), a gate insulating film was formed. The composition obtained in the present example was spin-coated at 2000 rpm for 60 seconds, pre-baked at 80° C. for 20 minutes, and cured with an i-line dose of 2400 mJ/cm² using a photomask. The substrate was then immersed in cyclopentanone as a developer at 25° C. to open only the pad portion of the gate electrode. Post-baking was performed at 150° C. for 1 hour.

Next, in the step of FIG. 7(3), source/drain electrodes were formed. Gold (Au) was deposited to a thickness of 50 nm on the gate insulating layer by resistance heating vacuum evaporation. Electrode processing was performed in the same manner as in the step of FIG. 7(1) for resist processing and etching processing.

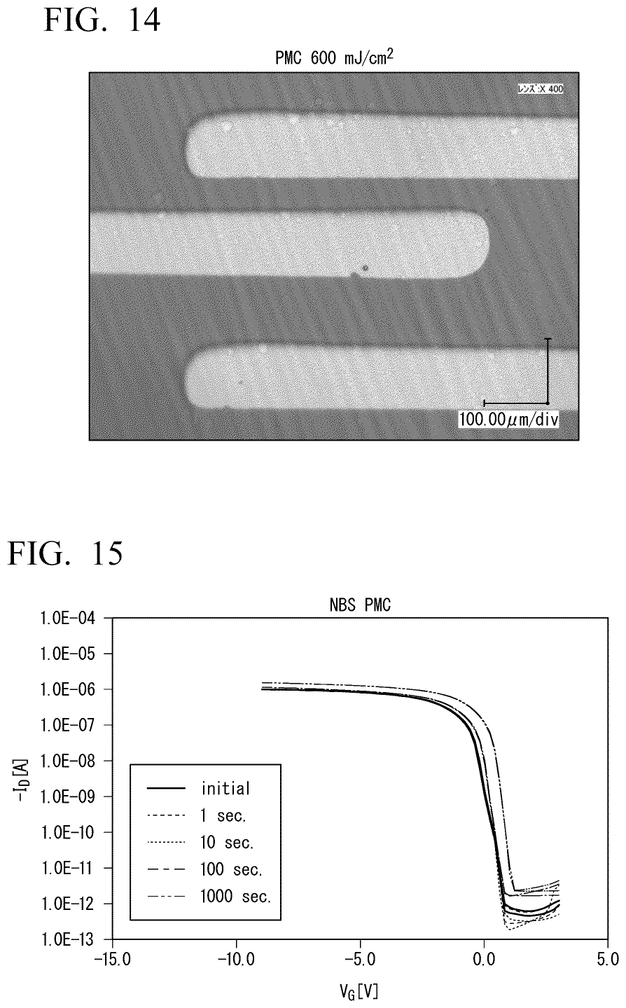

Finally, in the step of FIG. 7(4), the semiconductor layer was formed. After UV treatment of the substrate with the source/drain electrodes, a thiol-based self-assembled monolayer (SAM) was formed on the Au electrode surface by immersion. A semiconductor solution containing 0.5% by mass organic semiconductor and 0.2% by mass polystyrene dissolved in xylene was heated to 150° C., spin-coated at 1000 rpm for 30 seconds, and post-baked at 120° C. for 5 minutes. Finally, the semiconductor layer was patterned by wiping the electrode pads. The microscope image of the completed OTFT is shown in FIG. 14.

FIG. 15 shows the transfer characteristics and bias stress test results of the fabricated OTFT (channel length L=50 μm, channel width W=500 μm). The transfer characteristics were obtained at a source/drain voltage Vds=−2 V. The bias stress test was performed by applying a bias voltage Vg=−20 V between the source and gate, and characteristics were obtained after 1 second, 10 seconds, 100 seconds, and 1000 seconds of application. FIG. 10 shows the threshold voltage shift versus application time. For the gate insulating film of the present example, a threshold voltage shift of 0.67 V was confirmed after 1000 seconds of application.

### Comparative Example 1

PVCi was dissolved in cyclopentanone at 10% by mass to prepare the composition of this comparative example.

### [Preparation and Evaluation of Organic Insulating Film]

An organic insulating film was prepared and evaluated in the same manner as in Example 1, except that the composition of this comparative example was used instead of the composition of Example 1, and the obtained organic insulating film was developed with PGMEA. The results are shown in Table 1.

### [Manufacture and Evaluation of Organic Thin-Film Transistor]

As Comparative Example 1, in the OTFT manufacturing process of Example 1, the gate insulating film was made of PVCi. PVCi was dissolved in cyclopentanone at 10% by mass, spin-coated at 2000 rpm for 60 seconds, and pre-baked at 80° C. for 20 minutes. The film was then sufficiently cured with a low-pressure mercury lamp using a photomask. The substrate was immersed in cyclopentanone at 25° C. to open only the pad portion of the gate electrode. Post-baking was performed at 150° C. for 1 hour.

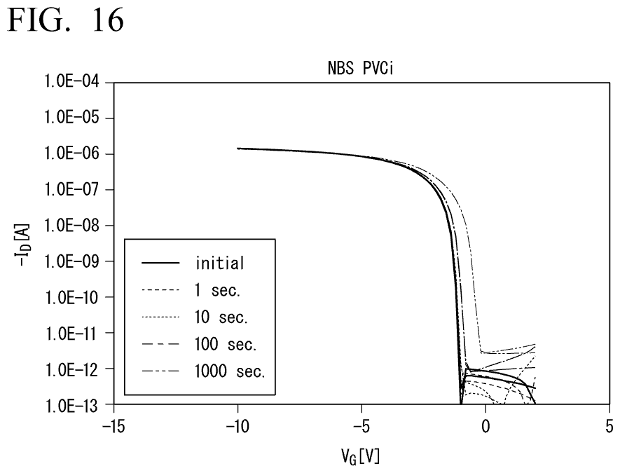

FIG. 16 shows the transfer characteristics and bias stress test results of the fabricated OTFT (channel length L=50 μm, channel width W=500 μm). The transfer characteristics were obtained at a source/drain voltage Vds=−2 V. The bias stress test was performed by applying a bias voltage Vg=−20 V between the source and gate, and characteristics were obtained after 1 second, 10 seconds, 100 seconds, and 1000 seconds of application. FIG. 9 shows the threshold voltage shift versus application time. For PVCi, a threshold voltage shift of 0.74 V was confirmed after 1000 seconds of application.

TABLE 1

| | | Exam- | | Exam- | Exam- | Exam- | Exam- | Exam- | | Exam- | Exam- |
|---|---|---|---|---|---|---|---|---|---|---|---|
| | | ple 1 | | ple 2 | ple 3 | ple 4 | ple 5 | ple 6 | | ple 7 | ple 8 |
| Composition | PVCi | 10.0 | | 10.0 | 10.0 | 10.0 | 10.0 | 10.0 | | 10.0 | 10.0 |
| | content | | | | | | | | | | |
| | (mass %) | | | | | | | | | | |
| | CH | 3.0 | | 0.3 | 0.5 | 1.0 | 10.0 | | | | |
| | content | | | | | | | | | | |
| | (mass %) | | | | | | | | | | |
| | MC | | | | | | | 1 | | 0.3 | 0.5 |
| | content | | | | | | | | | | |
| | (mass %) | | | | | | | | | | |
| | PMC | | | | | | | | | | |
| | Solvent | CPN | | CPN | CPN | CPN | CPN | CPN | | CPN | CPN |
| | Developer | PGMEA | | PGMEA | PGMEA | PGMEA | PGMEA | PGMEA | | PGMEA | PGMEA |
| Insulating | i-line | 1600 | | — | — | — | — | 200 | | 600 | 400 |
| film | sensitivity | | | | | | | | | | |
| evaluation | @ residual | | | | | | | | | | |
| | film ratio | | | | | | | | | | |
| | 85% | | | | | | | | | | |
| | (unit: | | | | | | | | | | |
| | mJ/cm2) | | | | | | | | | | |
| | i-line | 2400 | 6000 | 2400 | 2400 | 2400 | 2400 | 200 | 600 | 600 | 600 |
| | exposure | | | (82%) | (80%) | (79%) | (72%) | | | | |
| | (unit: | | | | | | | | | | |
| | mJ/cm2) | | | | | | | | | | |
| | After | 5.1 | 3.9 | 3.4 | 3.6 | 3.7 | 4 | 3.5 | 1.3 | 2.9 | 1.7 |
| | development | | | | | | | | | | |
| | Ra | | | | | | | | | | |
| | (unit: nm) | | | | | | | | | | |
| | Dielectric | 3 | 3 | 3.2 | 3.1 | 3.1 | 3.2 | 3.1 | 3 | — | — |
| | constant | | | | | | | | | | |
| | @100 | | | | | | | | | | |
| | kHz | | | | | | | | | | |
| | Insulating | >4 | >4 | >4 | >4 | >4 | >4 | >4 | >4 | — | — |
| | property | | | | | | | | | | |
| | @1.0E−8 | | | | | | | | | | |
| | A/cm2 | | | | | | | | | | |
| | (unit: | | | | | | | | | | |
| | MV/cm) | | | | | | | | | | |
| Evaluation | NBS | +0.4 | +0.5 | +0.4 | — | — | — | 0.4 | 0.3 | — | — |
| of OTFT | resistance | | | | | | | | | | |
| | ΔVTH. | | | | | | | | | | |
| | @−20 V, | | | | | | | | | | |
| | 1000 s | | | | | | | | | | |
| | (unit: V) | | | | | | | | | | |

TABLE 2

| | | | | | | | | | | | Compar- |
|---|---|---|---|---|---|---|---|---|---|---|---|
| | | | | | | | | | | | ative |
| | | Exam- | Exam- | Exam- | Exam- | Exam- | Exam- | Exam- | Exam- | | Exam- |
| | | ple 9 | ple 10 | ple 11 | ple 12 | ple 13 | ple 14 | ple 15 | ple 16 | | ple 1 |
| Composition | PVCi | 10.0 | 10.0 | 10.0 | 10.0 | 10.0 | 10.0 | 10.0 | | | 10.0 |
| | content | | | | | | | | | | |
| | (mass %) | | | | | | | | | | |
| | CH | | | 0.15 | 0.25 | 0.5 | 1.5 | 5.0 | | | |
| | content | | | | | | | | | | |
| | (mass %) | | | | | | | | | | |
| | MC | 3.0 | 10.0 | 0.15 | 0.25 | 0.5 | 1.5 | 5.0 | | | |
| | content | | | | | | | | | | |
| | (mass %) | | | | | | | | | | |
| | PMC | | | | | | | | 10.0 | | |
| | Solvent | CPN | CPN | CPN | CPN | CPN | CPN | CPN | CPN | | CPN |
| | Developer | PGMEA | PGMEA | PGMEA | PGMEA | PGMEA | PGMEA | PGMEA | CPN | | PGMEA |
| Insulating | i-line | 600 | 2000 | 400 | 400 | 400 | 400 | 4000 | 140 | | 24000 |
| film | sensitivity | | | | | | | | | | |
| evaluation | @ residual | | | | | | | | | | |
| | film ratio | | | | | | | | | | |
| | 85% | | | | | | | | | | |
| | (unit: | | | | | | | | | | |
| | mJ/cm²) | | | | | | | | | | |
| | i-line | 600 | 2000 | 200 | 200 | 200 | 200 | 200 | 200 | 600 | >20000 |
| | exposure | | | | | | | | | | |
| | (unit: | | | | | | | | | | |
| | mJ/cm²) | | | | | | | | | | |
| | After | 1.5 | 6.6 | 2.6 | 3.5 | 4 | 3.4 | 0.6 | 0.38 | 0.34 | 0.57 |
| | development | | | | | | | | | | |
| | Ra | | | | | | | | | | |
| | (unit: nm) | | | | | | | | | | |
| | Dielectric | 3.3 | — | — | — | — | — | — | 3.5 | — | 3.1 |
| | constant | | | | | | | | | | |
| | @100 | | | | | | | | | | |
| | kHz | | | | | | | | | | |
| | Insulating | >4 | — | — | — | — | — | — | 3.2 | — | >4 |
| | property | | | | | | | | | | |
| | @1.0E−8 | | | | | | | | | | |
| | A/cm² | | | | | | | | | | |
| | (unit: | | | | | | | | | | |
| | MV/cm) | | | | | | | | | | |
| Evaluation | NBS | +0.5 | — | — | — | — | — | — | +0.67 | — | +0.74 |
| of OTFT | resistance | | | | | | | | | | |
| | ΔV_{TH} | | | | | | | | | | |
| | @−20 V, | | | | | | | | | | |
| | 1000 s | | | | | | | | | | |
| | (unit: V) | | | | | | | | | | |

The meanings of the symbols in the tables are as follows:
PVCi: Polyvinyl cinnamate
CH: Chalcone
MC: Methoxychalcone
PMC: Poly(4-methoxychalcone)
CPN: Cyclopentanone
PGMEA: Propylene glycol 1-monomethyl ether 2-acetate

### DESCRIPTION OF REFERENCE NUMERALS

1, 11: Organic semiconductor layer
2, 12, 22: Substrate
3, 13, 33: Gate electrode
4, 14: Gate insulating layer
5, 15, 35: Source electrode
6, 16, 36: Drain electrode
22: Substrate
23: Electrode
24: Insulating layer

1. A photosensitive organic insulating material composition comprising:
a chalcone compound; and
polyvinyl cinnamate.

2. The photosensitive organic insulating material composition according to claim 1, wherein the chalcone compound is at least one selected from the group consisting of chalcone and methoxychalcone.

3. The photosensitive organic insulating material composition according to claim 1, wherein a ratio of a total mass of the chalcone compound to a mass of the polyvinyl cinnamate is 0.01 to 1.

4. The photosensitive organic insulating material composition according to claim 1, wherein a total amount of the chalcone compound and the polyvinyl cinnamate is 10% by mass to 30% by mass with respect to 100% by mass of the total photosensitive organic insulating material composition.

5. The photosensitive organic insulating material composition according to claim 1, wherein a total amount of the chalcone compound is 0.1% by mass to 15% by mass with respect to 100% by mass of the total photosensitive organic insulating material composition.

6. The photosensitive organic insulating material composition according to claim 1, having an absorption spectrum peak in a wavelength range of 300 to 370 nm.

7. An insulating film which is a photocured product of the photosensitive organic insulating material composition according to claim 1.

8. A gate insulating film that is a photocured product of the photosensitive organic insulating material composition according to claim 1.

9. A transistor having the gate insulating film according to claim 8.

10. An electronic device having the transistor according to claim 9.

11. A method for manufacturing a gate insulating film, comprising:
a step of applying the photosensitive organic insulating material composition onto a substrate, the photosensitive organic insulating material composition comprising a chalcone compound and polyvinyl cinnamate; and
a step of curing the photosensitive organic insulating material composition by exposure to form a gate insulating film.

12. A method for manufacturing a transistor having a gate insulating film, comprising:
a step of forming the gate insulating film by the method for manufacturing a gate insulating film according to claim 11.
